(19) United States
(12) Patent Application Publication
(10) Pub. No.: US 2006/0208302 A1
(43) Pub. Date: Sep. 21, 2006

(54) Non-volatile memory device having charge trap layer and method of fabricating the same

(75) Inventors: Yoo-Cheol Shin, Gyeonggi-do (KR); Jung-Dal Choi, Gyeonggi-do (KR); Ki-Tae Park, Gyeonggi-do (KR); Jong-Sun Sel, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/354,535

(22) Filed: Feb. 15, 2006

(30) Foreign Application Priority Data
Mar. 16, 2005 (KR) 10-2005-0021998

(51) Int. Cl. H01L 29/76

(52) U.S. Cl. 257/314

(57) ABSTRACT

A non-volatile memory device having a charge trap layer and a method of fabricating the same are provided. The non-volatile memory device includes a semiconductor substrate having an active region and a field region in contact with the active region. A trench isolation layer is formed within the semiconductor substrate field region to define the active region and has a protrusion higher than a top surface of the semiconductor substrate active region. A memory storage pattern is formed which crosses and extends from the semiconductor substrate active region to cover sidewalls of the protrusion of the trench isolation layer. A gate electrode is formed on the memory storage pattern and extends upward from the trench isolation layer.

### CROSS-REFERENCE TO RELATED APPLICATION

This application claims the benefit of Korean Patent Application No. 2005-0021998, filed on Mar. 16, 2005, the contents of which are hereby incorporated herein by reference in their entirety.

### FIELD OF THE INVENTION

The present invention relates to a semiconductor device and a method of fabricating the same, and more particularly, to a non-volatile memory device having a charge trap layer and a method of fabricating the same.

### BACKGROUND OF THE INVENTION

Semiconductor memory devices used to store data may be classified into volatile memory devices and non-volatile memory devices. When power is not supplied to volatile memory devices, they lose their stored data. However, non-volatile memory devices maintain their stored data even when power is not supplied to them. Accordingly, non-volatile memory devices are widely used in memory cards, mobile telecommunication systems, and so forth.

Non-volatile memory devices may be classified into floating gate non-volatile memory devices and charge trap non-volatile memory devices according to the kind of a memory storage layer which constitutes a unit cell of a memory cell. A floating gate non-volatile memory device uses a mechanism which accumulates charges in the floating gate whereas a charge trap non-volatile memory device uses a mechanism which accumulates charges in traps present in a dielectric layer such as a silicon nitride layer. A floating gate non-volatile memory device has a limit as to how small it can be, thus, a high voltage must be used for program and erasure. In contrast, a charge trap non-volatile memory device has low power and low voltage requirements, thereby allowing these devices to be very small.

A typical charge trap non-volatile memory device may have a metal nitride oxide semiconductor (MNOS) structure or a metal oxide nitride oxide semiconductor (MONOS) structure, wherein a dielectric layer, which acts as a charge storage layer, is disposed between a semiconductor substrate and a gate electrode, The MNOS type non-volatile memory device may store information using a trap site in the dielectric layer and a trap site of an interface, e.g., trap sites present at interfaces between a dielectric layer and a dielectric layer and between the dielectric layer and the semiconductor substrate.

FIGS. 1A to 1D are cross-sectional views illustrating a method of fabricating a conventional charge trap non-volatile memory device.

Referring to FIG. 1A, a semiconductor substrate 1 having an active region A and a field region F is prepared. A stacked insulating layer 16, a first conductive layer 20, and a hard mask layer 25 are sequentially formed on the semiconductor substrate 1. The stacked insulating layer 16 may be composed of a lower insulating layer 5, an intermediate insulating layer 10, and an upper insulating layer 15 which are sequentially stacked. The lower insulating layer 5 and the upper insulating layer 15 may be formed of a silicon oxide layer, and the intermediate insulating layer 10 may be formed of a silicon nitride layer. Subsequently, a photoresist pattern 30 having an opening for exposing a top surface of the field region F Is formed on the hard mask layer 25.

Referring to FIG. 1B, the hard mask layer (25 of FIG. 1A), the first conductive layer (20 of FIG. 1A), and the stacked insulating layer (16 of FIG. 1A) are sequentially patterned using the photoresist pattern (30 of FIG. 1A) as an etch mask, thereby forming a stacked insulating pattern 16a, a first conductive pattern 20a, and a hard mask pattern 25a which are sequentially stacked to expose the semiconductor substrate in the field region F.

The stacked insulating pattern 16a is composed of a lower insulating pattern 5a, an intermediate insulating pattern 10a, and an upper insulating pattern 15a which are sequentially stacked. As a result, the stacked insulating pattern 16a, the first conductive pattern 20a, and the hard mask pattern 25a are sequentially stacked on the semiconductor substrate in the active region A. Subsequently, the photoresist pattern (30 of FIG. 1A) may be removed.

Subsequently, the semiconductor substrate in the exposed field region F is anisotropically etched using the hard mask pattern 25a as an etch mask to form a trench 35 which defines the active region A. Further, a cleaning process may be performed on the semiconductor substrate where the trench 35 is formed.

Subsequently, the semiconductor substrate having the trench 35 may be thermally oxidized to form a thermal oxide layer (not shown) on inner walls of the trench 35. The thermal oxide layer is formed to cure etching damages applied to the semiconductor substrate during the anisotropic etching process for forming the trench 35.

Subsequently, an isolation insulating layer 40 is formed on the semiconductor substrate having the hard mask pattern 25a to fill the trench 35. The isolation insulating layer 40 may be formed of high density plasma (HDP) oxide.

Sidewalls of the stacked insulating pattern 16a may be damaged due to the anisotropic etching process for forming the trench 35 and processes for forming the thermal oxide layer on the inner walls of the trench 35. Specifically, the sidewalls of the stacked insulating pattern in contact with the trench 35 in the field region. F may be damaged due to the anisotropic etching process. Further, characteristics of the lower insulating pattern 5a and the upper insulating pattern 15a may be changed due to the process for forming the thermal oxide layer on the inner walls of the trench 35.

Subsequently, an isolation insulating layer 40 is formed on the semiconductor substrate having the hard mask pattern 25a to fill the trench 35. The isolation insulating layer 40 may be formed of a silicon oxide layer.

Referring to FIG. 1C, the isolation insulating layer 40 is planarized until a top surface of the hard mask pattern 25a is exposed so that a trench isolation layer 40a is formed to define the active region A.

Referring to FIG. 1D, the hard mask pattern (25a of FIG. 1C) is removed. A second conductive layer is then formed on the entire surface of the semiconductor substrate having the first conductive pattern (20a of FIG. 1C). The second conductive layer, the first conductive pattern (20a of FIG. 1C), and the stacked insulating pattern (16a of FIG. 1C) are sequentially patterned, thereby sequentially forming an upper conductive pattrn 45, a lower conductive pattern 20b, and a memory storage pattern 16b. In this case, the upper conductive pattern 45 crosses the active region A and extends upward from the trench isolation layer 40a in the field region F. The lower conductive pattern 20b is self-aligned below the upper conductive layer crossing the active region A. The memory storage pattern 16b is formed under the lower conductive pattern 20b. In this case, the memory storage pattern 16b may be composed of a tunnel insulating layer 5b, a charge trap layer 10b, and a blocking insulating layer 15b. The lower conductive pattern 20b and the upper conductive pattern 45 may constitute a gate electrode 46;

As described above, according to a method of fabricating a conventional non-volatile memory device, the sidewalls of the stacked insulating pattern 16a may be damaged while the stacked insulating layer 16 is etched to form the trench 35. Further, characteristics of the lower insulating pattern 5a and the upper insulating pattern 15a may be changed due to the process for forming the thermal oxide layer on the inner walls of the trench 35, so that defects may occur on sidewalls of the memory storage pattern 10b. Consequently, the characteristics of the non-volatile memory device may be degraded.

### SUMMARY OF THE INVENTION

Embodiments of the invention provide a non-volatile memory device capable of improving characteristic degradation and reliability of a memory storage pattern having a charge trap layer, and methods of fabricating the same.

According to some embodiments of the present invention, a non-volatile memory device includes a semiconductor substrate having an active region and a field region. A trench isolation layer is formed within the semiconductor substrate of the field region to define the active region, and has a protrusion higher than a top surface of the semiconductor substrate of the active region. A memory storage pattern crosses the semiconductor substrate of the active region and extends from the semiconductor substrate of the active region to cover sidewalls of the protrusion of the trench isolation layer. A gate electrode is formed on the memory storage pattern and extends upward from the trench isolation layer.

In some embodiments of the present invention, a top surface of the trench isolation layer may be higher than a top surface of the memory storage pattern on the active region.

In some embodiments, sidewalls of the protrusion of the trench isolation layer may be formed in the field region spaced apart from the semiconductor substrate edge of the active region by a predetermined distance, wherein the sidewalls may be spaced apart by at least the same distance as a thickness of the memory storage pattern covering the sidewalls of the protrusion of the trench isolation layer.

In some embodiments, the memory storage pattern may be composed of a tunnel insulating layer formed at least on the semiconductor substrate of the active region, and a charge trap layer and a blocking insulating layer sequentially stacked on the tunnel insulating layer and extending to the sidewalls of the protrusion of the trench isolation layer. In this case, the tunnel insulating layer may be one selected from the group consisting of a thermal oxide layer, a chemical vapor deposition (CVD) oxide layer, and an atomic layer deposition (ALD) oxide layer. The charge trap layer may be a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The blocking insulating layer may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

According to some embodiments, the gate electrode may be composed of a lower conductive pattern which is formed between the sidewalls of the protrusion of the trench isolation layer and has a top surface substantially disposed on the same line as a top surface of the trench isolation layer, and an upper conductive pattern which covers the lower conductive pattern and has a flat top surface extending upward from the trench isolation layer. In this case, the lower conductive pattern may be at least one layer selected from the group consisting of a polysilicon layer, a tantalum nitride (TaN) layer, a titanium nitride (TiN) layer, a tungsten nitride (WN) layer, and a cobalt silicide (CoSi) layer. The upper conductive pattern may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

According to some embodiments of the invention, a non-volatile memory device includes a semiconductor substrate having an active region and a field region. A trench isolation layer is formed within the semiconductor substrate of the field region to define the active region, and has a protrusion higher than a top surface of the semiconductor substrate of the active region. A lower conductive pattern is formed on the semiconductor substrate of the active region, and has a top surface higher than the top surface of the trench isolation layer. A memory storage pattern is formed which covers a bottom surface and sidewalls of the lower conductive pattern, and is self-aligned with the bottom surface of the lower conductive pattern and covers sidewalls of the lower conductive pattern adjacent to the field region. An upper conductive pattern is formed which covers the lower conductive pattern and extends upward from the trench isolation layer.

In some embodiments of the present invention, the top surface of the protrusion of the trench isolation layer may be disposed on or lower than an extended line of an intermediate region of the lower conductive pattern.

In some embodiments, sidewalls of the protrusion of the trench isolation layer adjacent to the semiconductor substrate of the active region may be formed in the field region spaced apart from the semiconductor substrate edge of the active region by a predetermined distance, wherein the sidewalls may be spaced apart by at least the same distance as a thickness of the memory storage pattern covering the sidewalls of the lower conductive pattern.

In some embodiments, the memory storage pattern may be composed of a tunnel insulating layer formed at least on the semiconductor substrate of the active region, and a charge trap layer and a blocking insulating layer sequentially stacked on the tunnel insulating layer and extending from the tunnel insulating layer to cover the sidewalls of the lower conductive pattern. The tunnel insulating layer may be one selected from the group consisting of a thermal oxide layer, a CVD oxide layer, and an ALD oxide layer. The charge trap layer may be a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The blocking insulating layer may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In some embodiments, the lower conductive pattern may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

In some embodiments, the upper conductive pattern may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

According to some embodiments of the invention, a method of fabricating a non-volatile memory device includes preparing a semiconductor substrate having an active region and a field region. A trench isolation layer, which has a protrusion higher than a surface of the semiconductor substrate of the active region, is formed within the semiconductor substrate of the field region. A stacked insulating layer is formed to cover the semiconductor substrate of the active region and the protrusion of the trench isolation layer, and the stacked insulating layer on the active region has a top surface lower than a top surface of the trench isolation layer. A first conductive layer is formed on the semiconductor substrate having the stacked insulating layer. The first conductive layer and the stacked insulating layer are planarized until the top surface of the trench isolation layer is exposed, so that a first conductive pattern remaining on the active region is formed while a stacked insulating pattern is formed which covers the semiconductor substrate of the active region and the sidewalls of the protrusion of the trench isolation layer. A second conductive layer is formed on the entire surface of the semiconductor substrate having the stacked insulating pattern and the first conductive pattern. The second conductive layer, the first conductive pattern, and the stacked insulating pattern are sequentially patterned, so that an upper conductive pattern crossing the active region and extending upward from the trench isolation layer, a lower conductive pattern disposed between sidewalls of the protrusion of the trench isolation layer and below the upper conductive pattern on the active region, and a memory storage pattern covering the semiconductor substrate of the active region and the sidewalls of the protrusion of the trench isolation layer, are sequentially formed.

In some embodiments of the present invention, the sidewalls of the protrusion of the trench isolation layer may be formed in the field region spaced apart from the semiconductor substrate edge of the active region by a predetermined distance, wherein the sidewalls may be formed in the field region spaced apart by at least the same distance as a thickness of the stacked insulating layer covering the sidewalls of the protrusion of the trench isolation layer.

In some embodiments, the stacked insulating layer may be composed of a lower insulating layer formed at least on the semiconductor substrate of the active region, and an intermediate insulating layer and an upper insulating layer conformally and sequentially stacked on the entire surface of the semiconductor substrate having the active region. The lower insulating layer may be formed of one selected from the group consisting of a thermal oxide layer, a CVD oxide layer, and an ALD oxide layer. The intermediate insulating layer may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The upper insulating layer may be formed of at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In some embodiments, the first conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

In some embodiments, the second conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

In some embodiments, the invention is directed to a method of fabricating a non-volatile memory device which includes preparing a semiconductor substrate having an active region and a field region. A preliminary trench isolation layer, which has a protrusion higher than a surface of the semiconductor substrate of the active region, is formed within the semiconductor substrate of the field region. A stacked insulating layer is formed to cover the semiconductor substrate of the active region and the protrusion of the preliminary trench isolation layer, and the stacked insulating layer on the active region has a top surface lower than a top surface of the preliminary trench isolation layer. A first conductive layer is formed on the semiconductor substrate having the stacked insulating layer. The first conductive layer and the stacked insulating layer are planarized until the top surface of the preliminary trench isolation layer is exposed, so that a first conductive pattern remaining on the active region is formed while a stacked insulating pattern is formed which covers the semiconductor substrate of the active region and the sidewalls of the protrusion of the preliminary trench isolation layer. The preliminary trench isolation layer is selectively and partially etched to form a trench isolation layer which has a top surface higher than a surface of the semiconductor substrate of the active region and lower than an intermediate region of the first conductive pattern. A second conductive layer is formed on the entire surface of the semiconductor substrate having the trench isolation layer. The second conductive layer, the first conductive pattern, and the stacked insulating pattern are sequentially patterned, so that an upper conductive pattern crossing the active region and extending upward from the trench isolation layer, a lower conductive pattern disposed below the upper conductive pattern on the active region, and a memory storage pattern disposed below the lower conductive pattern and covering the sidewalls of the lower conductive pattern adjacent to the field region, are sequentially formed.

In some embodiments of the present invention, the sidewalls of the protrusion of the preliminary trench isolation layer may be formed in the field region spaced apart from the semiconductor substrate edge of the active region by a predetermined distance, wherein the sidewalls may be formed in the field region spaced apart by at least the same distance as a thickness of the stacked insulating layer covering the sidewalls of the protrusion of the preliminary trench isolation layer.

In some embodiments, the stacked insulating layer may be composed of a lower insulating layer formed at least on the semiconductor substrate of the active region, and an intermediate insulating layer and an upper insulating layer conformally and sequentially stacked on the entire surface of the semiconductor substrate having the active region. In this case, the lower insulating layer may be formed of one selected from the group consisting of a thermal oxide layer, a CVD oxide layer, and an ALD oxide layer. The intermediate insulating layer may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The upper insulating layer may be formed of at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In some embodiments, the first conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

In some embodiments, the second conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawing is not necessarily to scale, emphasis instead being placed upon illustrating the principles of the invention.

FIGS. 1A to 1D are cross-sectional views illustrating a method of fabricating a conventional non-volatile memory device.

FIGS. 2 to 4 are perspective views of non-volatile memory devices in accordance with exemplary embodiments of the present invention.

FIGS. 5 to 15 are cross-sectional views illustrating methods of fabricating non-volatile memory devices in accordance with exemplary embodiments of the present invention.

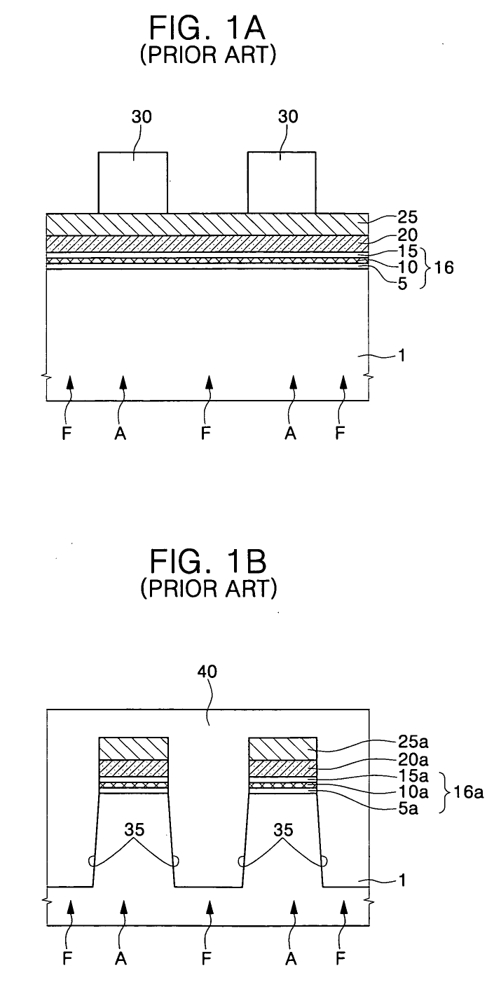

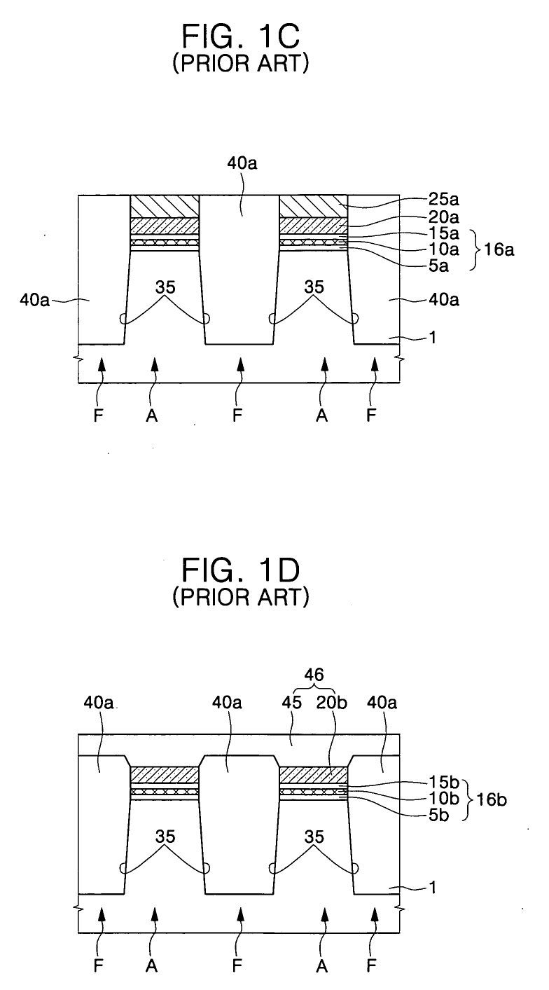

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like numbers refer to like elements throughout the specification.

The present invention now is described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In the figures, the thickness of certain lines, layers, components, elements or features may be exaggerated for clarity. Broken lines illustrate optional features or operations unless specified otherwise. All publications, patent applications, patents, and other references mentioned herein are incorporated herein by reference in their entireties.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Ya” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as is illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a “first” element, component, region, layer or section discussed below could also be termed a “second” element, component, region, layer or section without departing from the teachings of the present invention. The sequence of operations (or steps) is not limited to the order presented in the claims or figures unless specifically indicated otherwise.

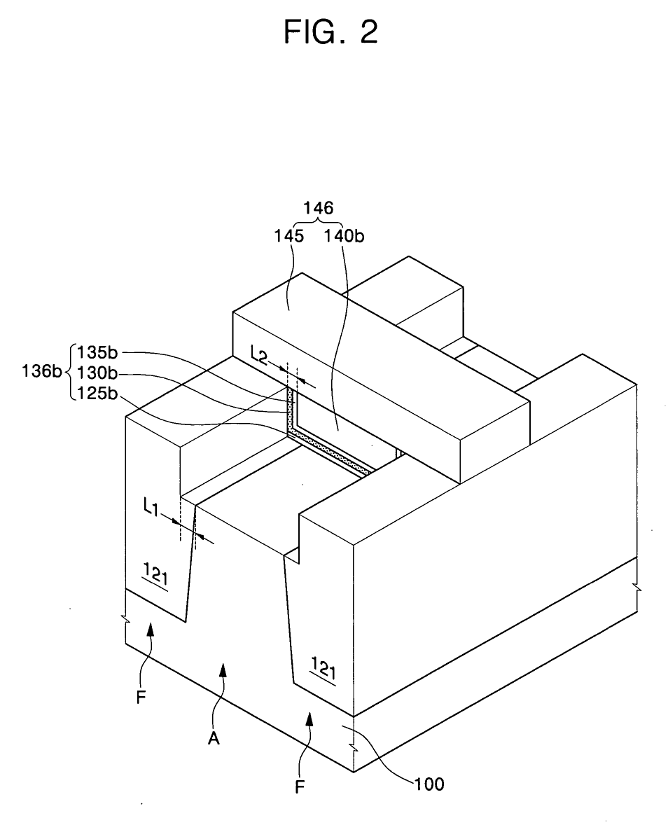

FIGS. 2 to 4 are perspective views of non-volatile memory devices in accordance with exemplary embodiments of the present invention.

A non-volatile memory device according to an exemplary embodiment of the present invention will now be described with reference to FIG. 2.

Referring to FIG. 2, a semiconductor substrate 100 includes an active region A and a field region F in contact with the active region A. A trench isolation layer 121 is disposed in the semiconductor substrate 100 of the field region F to define the active region A and has a protrusion higher than a top surface of the semiconductor substrate of the active region A. In this case, sidewalls of the protrusion of the trench isolation layer 121 adjacent to the semiconductor substrate of the active region A may be disposed in the field region F spaced apart from an edge of the surface of the semiconductor substrate of the active region A by a predetermined distance L1. The trench isolation layer 121 may comprise a silicon oxide layer. The trench isolation layer 121 may electrically isolate the active region A from its adjacent active regions.

A memory storage pattern 136b crosses the semiconductor substrate of the active region A and extends toward the sidewalls of the protrusion of the trench isolation layer 121. A top surface of the protrusion of the trench isolation layer 121 may be higher than a top surface of the memory storage pattern on the active region A. The sidewalls of the protrusion of the trench isolation layer 121 adjacent to the semiconductor substrate of the active region A are disposed in the field region F spaced apart from an edge of the semiconductor substrate of the active region A by a predetermined distance L1, which may be at least the same distance as a thickness L2 of the memory storage pattern covering the sidewalls of the protrusion of the trench isolation layer 121.

The memory storage pattern 136b may be composed of a tunnel insulating layer 125b disposed on the active region A, and a charge trap layer 130b and a blocking insulating layer 135b which are sequentially stacked on the tunnel insulating layer 125b and extend to cover the sidewalls of the protrusion of the trench isolation layer 121. The charge trap layer 130b may act as a charge storage layer. The tunnel insulating layer 125b may be composed of a thermal oxide layer. The charge trap layer 130b may be composed of a high-k dielectric layer. The high-k dielectric layer may be formed of at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The blocking insulating layer 135b may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

A gate electrode 146 covers the memory storage pattern 136b and extends upward from the trench isolation layer 121. In this case, the gate electrode 146 covers the memory storage pattern 136b on the active region A, and is composed of a lower conductive pattern 140b having a top surface on the substantially same line as a top surface of the trench isolation layer 121, and an upper conductive pattern 145 covering the lower conductive pattern 140b and having a flat top surface extending upward from the trench isolation layer 121.

In this case, the lower conductive pattern 140b may be at least one layer selected from the group consisting of a polysilicon layer, a tantalum nitride (TaN) layer, a titanium nitride (TiN) layer, a tungsten nitride (WN) layer, and a cobalt silicide (CoSi) layer. The upper conductive pattern 145 may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

Top surfaces of the trench isolation layer 121 are in direct contact with the gate electrode 146. As a result, the memory storage pattern 136b is not formed on the trench isolation layer 121 which electrically isolates the active region A from its adjacent active regions, so that disturbance which might occur at the time of operating the non-volatile memory device due to the adjacent cell may be minimized even when pitches of the active and field regions are reduced due to high integration of the non-volatile memory device. That is, the memory storage pattern 136b is isolated by the trench isolation layer 121, so that charges trapped in the memory storage pattern 136b, in particular, the charge trap layer 130b, may be suppressed from moving between cells. Accordingly, the characteristics of the non-volatile memory device, e.g. data retention capability may be enhanced.

Further, the sidewalls of the protrusion of the trench isolation layer 121 adjacent to the semiconductor substrate of the active region A are disposed in the field region F spaced apart from the semiconductor substrate edge of the active region A by a predetermined distance L1. In this case, the sidewalls may be disposed in the field region F spaced apart by at least the same distance as the thickness L2 of the memory storage pattern covering the sidewalls of the protrusion of the trench isolation layer 121. That is, the memory storage pattern 136b extends to the sidewalls of the protrusion of the trench isolation layer 121 from a top surface of the semiconductor substrate of the active region A. Consequently, the memory storage pattern may have a stable structure at an interface between the active region A and the field region F. Characteristics and reliability degradation of the memory storage pattern may also be improved. Accordingly, characteristics of the non-volatile memory device, e.g. program and erase operations, and endurance may be enhanced.

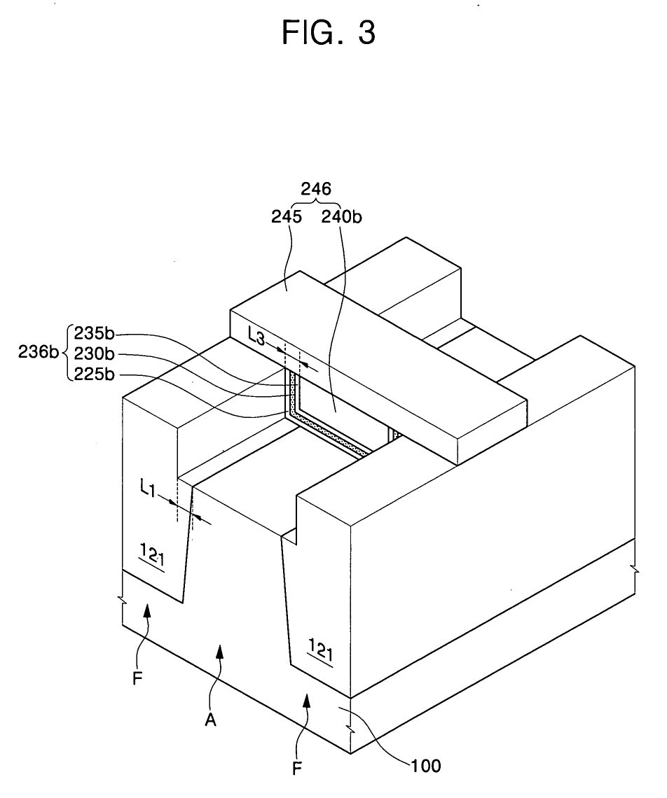

Next, a non-volatile memory device according to other exemplary embodiments of the present invention will be described with reference to FIG. 3.

Referring to FIG. 3, a semiconductor substrate 100 includes an active region A and a field region F in contact with the active region A. A trench isolation layer 121 is disposed in the semiconductor substrate 100 of the field region F to define the active region A, and has a protrusion higher than a top surface of the semiconductor substrate of the active region A. In this case, sidewalls of the protrusion of the trench isolation layer 121 adjacent to the semiconductor substrate of the active region A may be disposed in the field region F spaced apart from an edge of the surface of the semiconductor substrate of the active region A by a predetermined distance L1.

A conformal memory storage pattern 236b crosses the semiconductor substrate of the active region A and extends toward the sidewalls of the protrusion of the trench isolation layer 121. A top surface of the protrusion of the trench isolation layer 121 may be higher than a top surface of the memory storage pattern on the active region A. The sidewalls of the protrusion of the trench isolation layer 121 adjacent to the semiconductor substrate of the active region A are disposed in the field region F spaced apart from an edge of the semiconductor substrate of the active region A by a predetermined distance L1. In this case, the sidewalls may be disposed in the field region F spaced apart by at least the same distance as a thickness L3 of the memory storage pattern covering the sidewalls of the protrusion of the trench isolation layer 121.

The memory storage pattern 236 may be composed of a tunnel insulating layer 225b, a charge trap layer 230b, and a blocking insulating layer 235b which are sequentially stacked.

The tunnel insulating layer 225b may be formed of one of a chemical vapor deposition (CVD) oxide layer and an atomic layer deposition (ALD) oxide layer. The charge trap layer 230b may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The blocking insulating layer 235b may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

A gate electrode 246 covers the memory storage pattern 236b and extends upward from the trench isolation layer 121. In this case, the gate electrode 246 covers the memory storage pattern 236b on the active region A, and is composed of a lower conductive pattern 240b having a top surface on the substantially same line as a top surface of the trench isolation layer 121, and an upper conductive pattern 245 covering the lower conductive pattern 240b and having a flat top surface extending upward from the trench isolation layer 121.

In this case, the lower conductive pattern 240b may be at least one layer selected from the group consisting of a polysilicon layer, a tantalum nitride (TaN) layer, a titanium nitride (TiN) layer, a tungsten nitride (WN) layer, and a cobalt silicide (CoSi) layer. The upper conductive pattern 245 may be at least one layer selected from the group consisting of a polysilicon layer, a tantalum nitride (TaN) layer, a titanium nitride (TiN) layer, a tungsten nitride (TiN) layer, and a cobalt silicide (CoSi) layer.

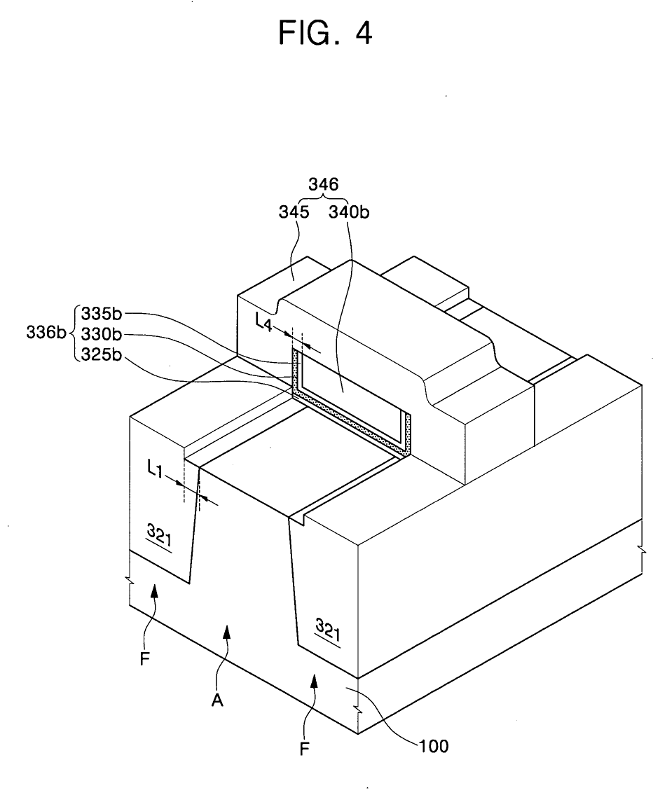

Next, a non-volatile memory device according to yet other exemplary embodiments of the present invention will be described with reference to FIG. 4.

Referring to FIG. 4, a semiconductor substrate 100 includes an active region A and a field region F in contact with the active region A. A trench isolation layer 321 is disposed in the semiconductor substrate 100 of the field region F to define the active region A, and has a protrusion higher than a top surface of the semiconductor substrate of the active region A. In this case, sidewalls of the protrusion of the trench isolation layer 321 may be disposed in the field region F spaced apart from an edge of the surface of the semiconductor substrate of the active region A by a predetermined distance L1. The trench isolation layer 321 may comprise a silicon oxide layer.

A lower conductive pattern 340b is disposed on the semiconductor substrate of the active region A. In this case, a top surface of the lower conductive pattern 340b is higher than a top surface of the trench isolation layer 321. More preferably, the top surface of the protrusion of the trench isolation layer 321 may be higher than a top surface of the semiconductor substrate of the active region A, and may be lower than or disposed on an extended line of an intermediate region of the lower conductive pattern 340b. The lower conductive pattern 340b may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer. Sidewalls of the lower conductive pattern 340b in contact with the field region F may be formed at least on the semiconductor substrate of the active region A.

A memory storage pattern 336b surrounds a bottom surface and sidewalls of the lower conductive pattern 340b, is self-aligned with the bottom surface of the lower conductive pattern 340b, and covers the sidewalls adjacent to the field region F of the lower conductive pattern 340b. The memory storage pattern 336b may be composed of a tunnel insulating layer 325b formed at least on the semiconductor substrate of the active region A, and a charge trap layer 330b and a blocking insulating layer 335b sequentially stacked on the tunnel insulating layer 325b and extending from the tunnel insulating layer 325b to cover sidewalls adjacent to the field region F of the lower conductive pattern 340b.

The tunnel insulating layer 325b may be at least one layer selected from the group consisting of a thermal oxide layer, a CVD oxide layer, and an ALD oxide layer. The charge trap layer 330b may be a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The blocking insulating layer 335b may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In this case, a thickness L4 of the memory storage pattern covering the sidewalls of the protrusion of the trench isolation layer 321 may be the same as or smaller than a distance L1 between the sidewalls of the protrusion of the trench isolation layer 321 and the semiconductor substrate edge of the active region A. That is, the sidewalls of the protrusion of the trench isolation layer 321 adjacent to the semiconductor substrate of the active region A are formed in the field region F spaced apart from the semiconductor substrate edge of the active region A by the predetermined distance L1, and in this case, the sidewalls may be formed in the field region F spaced apart by at least the same distance as the thickness L4 of the memory storage pattern covering the sidewalls of the protrusion of the trench isolation layer 321.

An upper conductive pattern 345 is disposed which covers a top surface of the lower conductive pattern 340b and extends upward from the trench isolation layer 321. The upper conductive pattern 345 may be at least one layer selected from the group consisting of a polysilicon layer, a tantalum nitride (TaN) layer, a titanium nitride (TiN) layer, a tungsten nitride (WN) layer, and a cobalt silicide (CoSi) layer. The upper conductive pattern 345 and the lower conductive pattern 340b are electrically connected to each other to form a gate electrode 346.

A bottom surface of the upper conductive pattern 345 on the trench isolation layer 321 is lower than the top surface of the lower conductive pattern 340b. That is, the lower conductive pattern 340b has a top surface higher than the top surface of the trench isolation layer 321. Preferably, the top surface of the protrusion of the trench isolation layer 321 may be lower than or disposed on an extended line of an intermediate region of the lower conductive pattern 340b.

A predetermined part of the upper conductive pattern is present between the lower conductive pattern 340b and another lower conductive pattern (not shown) adjacent to the pattern 340b. Accordingly, coupling capacitance which might occur between the lower conductive pattern 340b and the other lower conductive pattern may be minimized.

In addition, the top surface of the protrusion of the trench isolation layer 321 is in direct contact with the gate electrode 346. As a result, the memory storage pattern 336b is not formed on the trench isolation layer 321 which electrically isolates the active region A from its adjacent active regions, so that disturbance which might occur at the time of operating the non-volatile memory device due to the adjacent cell may be minimized even when the pitches of the active and field regions are reduced due to high integration of the non-volatile memory device. That is, the memory storage pattern 336b is isolated by the trench isolation layer 321, so that charges trapped in the memory storage pattern 336b, in particular, the charge trap layer 330b, may be suppressed from moving between cells. Accordingly, the characteristics of the non-volatile memory device, e.g. data retention capability may be enhanced.

In addition, the memory storage pattern may extend to the field region F from the active region A by a predetermined portion. Accordingly, the structure of the memory storage pattern may be stabilized on the active region A where program and erase operations of the non-volatile memory device are executed. That is, the structure of the memory storage pattern may be stabilized at an interface between the active region A and the field region F.

Consequently, characteristic degradation and reliability of the memory storage pattern may be improved. Accordingly, the characteristics of the non-volatile memory device, e.g. program and erase operations, and endurance may be enhanced.

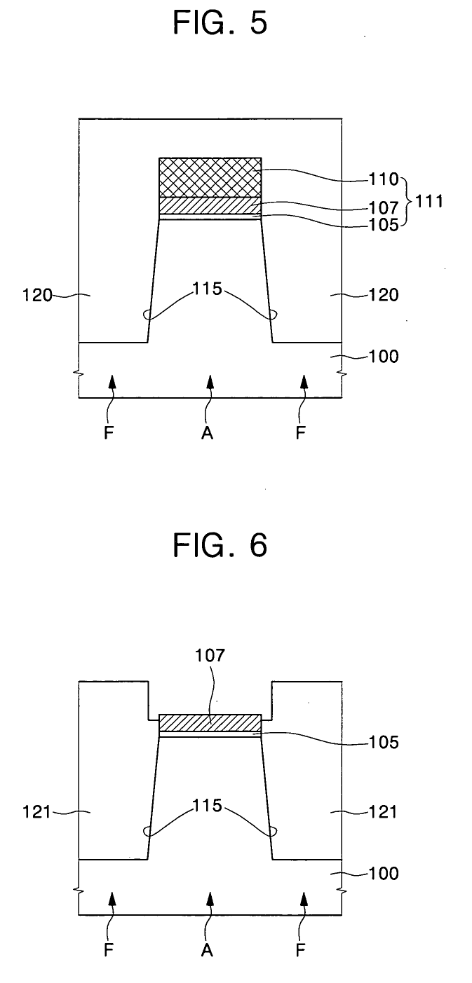

FIGS. 5 to 15 are cross-sectional views illustrating methods of fabricating non-volatile memory devices in accordance with exemplary embodiments of the present invention.

First, a method of fabricating the non-volatile memory device according to one embodiment of the present invention will now be described with reference to FIGS. 5 to 10.

Referring to FIG. 5, a semiconductor substrate 100 having an active region A and a field region F in contact with the active region A is prepared. A mask pattern 111 is formed on the semiconductor substrate 100 to expose the semiconductor substrate of the field region F. The mask pattern 111 may be composed of a buffer oxide pattern 105, a sacrificial conductive pattern 107, and a hard mask pattern 110 which are sequentially stacked. The buffer oxide pattern 105 may be formed of a thermal oxide layer. The sacrificial conductive pattern 107 may be formed of a material layer having an etch selectivity with respect to the hard mask pattern 110. For example, when the hard mask pattern 110 is formed of a silicon nitride layer, the sacrificial conductive pattern 107 may be formed of a polysilicon layer.

Subsequently, the exposed semiconductor substrate of the field region F is anisotropically etched using the mask pattern 111 as an etch mask to form a trench 115 which defines the active region A. A trench isolation insulating layer 120 is formed on the entire surface of the semiconductor substrate having the trench 115 to fill the trench 115. The trench isolation insulating layer 120 may be formed of a silicon oxide layer. For example, the trench isolation insulating layer 120 may be formed of a high density plasma (HDP) oxide layer.

In the meantime, before the trench isolation insulating layer 120 is formed, the semiconductor substrate having the trench 115 may be thermally oxidized to form a thermal oxide layer on inner walls of the trench 115. The thermal oxide layer is formed to cure etching damages applied to the semiconductor substrate 100 during the anisotropic etching process for forming the trench 115.

The hard mask pattern 110 is formed of an insulating layer having an etch selectivity with respect to the trench isolation insulating layer 120. For example, when the trench isolation insulating layer 120 is formed of a silicon oxide layer, the hard mask pattern 110 may be formed of a silicon nitride layer.

Referring to FIG. 6, the trench isolation insulating layer (120 of FIG. 5) is planarized until a top surface of the hard mask pattern 110 is exposed, so that a trench isolation layer 121 is formed which fills the trench 115 and has a top surface substantially on the same line as a top surface of the hard mask pattern 110. As a result, the trench isolation layer 121 has a protrusion higher than a surface of the semiconductor substrate of the active region A. The active region A may be electrically isolated from its adjacent active regions by the trench isolation layer 121. The planarization process is preferably performed using a chemical mechanical polishing (CMP) process.

Subsequently, the hard mask pattern 110 is removed to expose the sacrificial conductive pattern 107. Accordingly, upper sidewalls of the protrusion of the trench isolation layer 121 may be exposed.

Subsequently, an isotropic etching may be performed on the exposed protrusion of the trench isolation layer 121 using the exposed sacrificial conductive pattern 107 as an etch mask. In this case, the isotropic etching may employ dry etching which may etch the exposed protrusion of the trench isolation layer 121 by about 100A or less. When the trench isolation layer 121 is formed of a silicon oxide layer, the isotropic etching may be performed using an etchant containing hydrofluoric acid or a buffered oxide etchant (BOE). Accordingly, the upper sidewalls of the protrusion of the trench isolation layer 121 may be formed in the field region F.

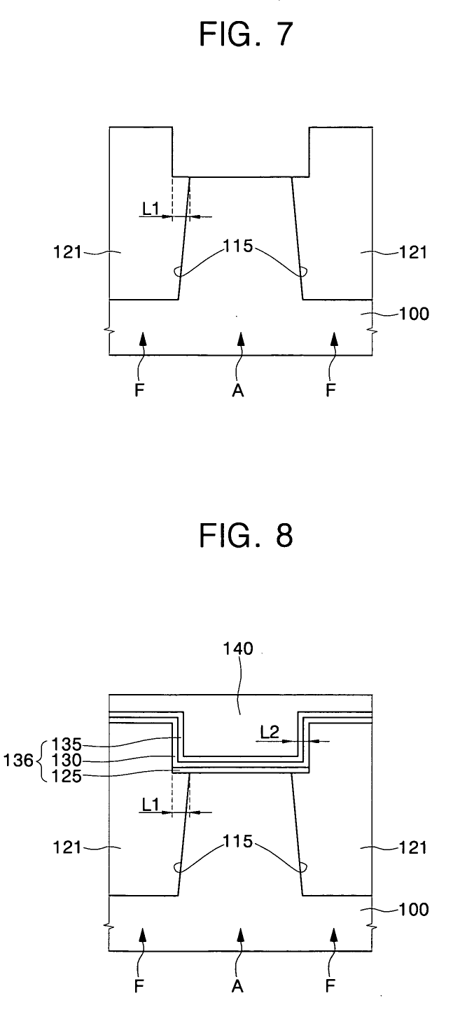

Referring to FIG. 7, the sacrificial conductive pattern (107 of FIG. 6) may be selectively removed to expose the buffer oxide pattern (105 of FIG. 6). Subsequently, the exposed buffer oxide pattern (105 of FIG. 6) is removed to expose the semiconductor substrate of the active region A. In this case, when the buffer oxide pattern (105 of FIG. 6) is formed of a silicon oxide layer such as a thermal oxide layer, the buffer oxide pattern (105 of FIG. 6) may be removed by an etching process which employs an oxide etchant containing hydrofluoric acid or a BOE. In this case, sidewalls of the protrusion of the trench isolation layer 121 may be etched by the process of removing the buffer oxide pattern (105 of FIG. 6) by a predetermined amount. As a result, the sidewalls of the protrusion of the trench isolation layer 121 may be formed in the field region spaced apart from the semiconductor substrate edge of the active region A in contact with the field region F by a predetermined distance L1. In this case, a height difference of about 500A or more may be present between the top surface of the protrusion of the trench isolation layer 121 and the surface of the semiconductor substrate of the active region A.

In the meantime, the mask pattern 111 may be formed of a buffer oxide pattern and a hard mask pattern which are sequentially stacked. In this case, after the trench isolation layer substantially having the same top surface as the hard mask pattern is formed within the semiconductor substrate of the field region F, the hard mask pattern may be removed. Subsequently, the buffer oxide pattern may be removed to expose the semiconductor substrate of the active region. In this case, the sidewalls of the protrusion of the trench isolation layer may be formed in the field region F spaced apart from the semiconductor substrate edge of the active region A by a predetermined distance L1.

Referring to FIG. 8, a stacked insulating layer 136 is formed on the entire surface of the semiconductor substrate having the trench isolation layer 121. The stacked insulating layer on the active region A has a top surface lower than the top surface of the protrusion of the trench isolation layer 121. The stacked insulating layer 136 may include a lower insulating layer 125, an intermediate insulating layer 130, and an upper insulating layer 135. To detail this, the lower insulating layer 125 is formed on the exposed semiconductor substrate of the active region. The lower insulating layer 125 may be formed of a thermal oxide layer. The intermediate insulating layer 130 and the upper insulating layer 135 are sequentially stacked on the entire surface of the semiconductor substrate having the lower insulating layer 125. The intermediate insulating layer 130 may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The upper insulating layer 135 may be formed of at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In this case, a thickness L2 of the stacked insulating layer covering the sidewalls of the protrusion of the trench isolation layer 121 may be the same as or less than a distance L1 between the sidewalls of the protrusion of the trench isolation layer 121 and the semiconductor substrate edge of the active region A. That is, the sidewalls of the protrusion of the trench isolation layer 121 adjacent to the semiconductor substrate of the active region A are formed in the field region F spaced apart from the semiconductor substrate edge of the active region by the predetermined distance L1, and the sidewalls may be formed in the field region F spaced by at least the same distance as the thickness L2 of the stacked insulating layer covering the sidewalls of the protrusion of the trench isolation layer 121.

Subsequently, a first conductive layer 140, which fills a space between the sidewalls of the protrusion of the trench isolation layer 121, is formed on the entire surface of the semiconductor substrate having the stacked insulating layer 136. The first conductive layer 140 may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

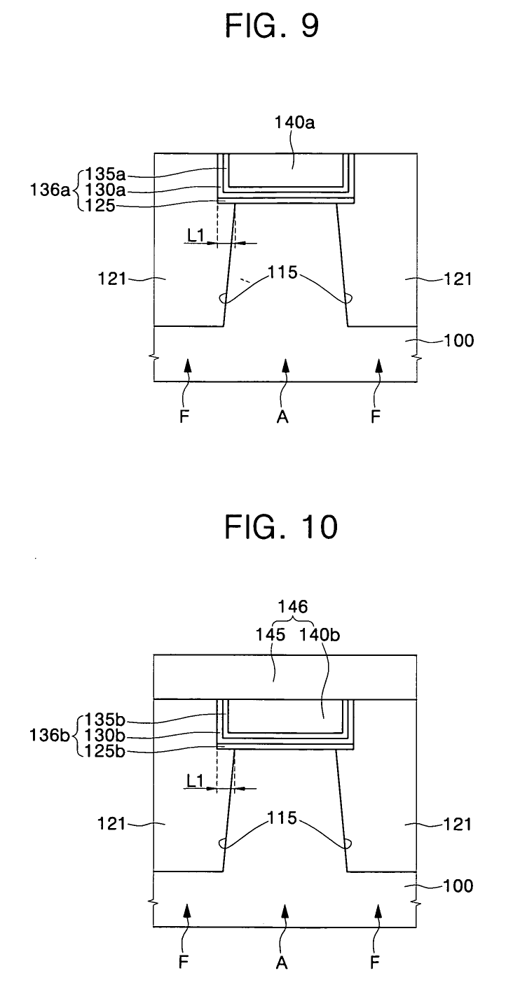

Referring to FIG. 9, the first conductive layer (140 of FIG. 8) and the stacked insulating layer (136 of FIG. 8) are planarized until a top surface of the trench isolation layer 121 is exposed, thereby forming a first conductive pattern 140a and a stacked insulating pattern 136a. The planarization process may employ a CMP process or an etchback process. The stacked insulating pattern 136a may be composed of a lower insulating layer 125 formed on the semiconductor substrate of the active region A, and an intermediate insulating pattern 130a and an upper insulating pattern 135a sequentially covering the lower insulating layer 125 and the sidewalls of the protrusion of the trench isolation layer 121.

Referring to FIG. 10, a second conductive layer having a flat top surface is formed on the entire surface of the semiconductor substrate having the first conductive pattern 140a and the stacked insulating pattern 136a. The second conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

Subsequently, the second conductive layer, the first conductive pattern 140a, and the stacked insulating pattern 136a are sequentially patterned, so that an upper conductive pattern 145 crossing the active region A and extending upward from the trench isolation layer 121, a lower conductive pattern 140b disposed between the sidewalls of the protrusion of the trench isolation layer 121 and below the upper conductive pattern on the active region A, and a memory storage pattern 136b interposed between the semiconductor substrate of the active region A and the lower conductive pattern 140b and between the sidewalls of the protrusion of the trench isolation layer 121 and the lower conductive pattern 140b are formed. The memory storage pattern 136b may be composed of a tunnel insulating layer 125b crossing the active region A, and a charge trap layer 130b and a blocking insulating layer 135b sequentially stacked and covering the tunnel insulating layer and extending to the sidewalls of the protrusion of the trench isolation layer 121. The lower conductive pattern 140b and the upper conductive pattern 145 may be electrically connected to each other to form a gate electrode 146.

The top surface of the protrusion of the trench isolation layer 121 is in direct contact with the gate electrode 146. As a result, the memory storage pattern 136b is not formed on the trench isolation layer 121 which electrically isolates the active region A from its adjacent active regions, so that disturbance which can occur at the time of operating the non-volatile memory device due to the adjacent cell may be minimized even when the pitches of the active and field regions are reduced due to high integration of the non-volatile memory device. That is, the memory storage pattern 136b is isolated by the trench isolation layer 121, so that charges trapped in the memory storage pattern 136b, in particular, the charge trap layer 130b, may be suppressed from moving between cells. Accordingly, the characteristics of the non-volatile memory device, e.g. data retention capability may be enhanced.

Further, the sidewalls of the protrusion of the trench isolation layer 121 adjacent to the semiconductor substrate of the active region A are formed in the field region F spaced apart from the semiconductor substrate edge of the active region A by a predetermined distance L1. In this case, the sidewalls may be formed in the field region F spaced apart by at least the same distance as the thickness L2 of the memory storage pattern covering the sidewalls of the protrusion of the trench isolation layer 121. As a result, the memory storage pattern may be formed without any damage at an interface between the active region A and the field region F. That is, the memory storage pattern 136b extends to the sidewalls of the protrusion of the trench isolation layer 121 from the surface of the semiconductor substrate of the active region A. Consequently, the memory storage pattern may be formed at the interface between the active region A and the field region F. Accordingly, characteristic degradation and reliability of the memory storage pattern may be improved. Furthermore, the characteristics of the non-volatile memory device, e.g. program and erase operations, and endurance may be enhanced.

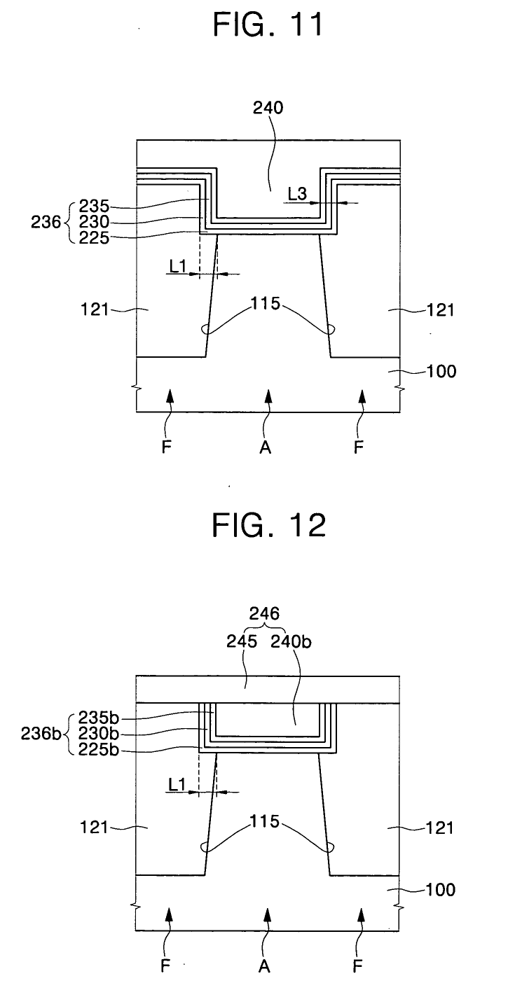

Next, a method of fabricating a non-volatile memory device according to other exemplary embodiments of the present invention will be described with reference to FIGS. 11 and 12. Hereinafter, processes up to the formation of the trench isolation layer 121 are substantially the same as the method described with reference to FIGS. 5 to 7, and will not be described further with respect to FIGS. 11 to 12.

Referring to FIG. 11, a conformal stacked insulating layer 236 is formed on the entire surface of the semiconductor substrate having the trench isolation layer 121. The stacked insulating layer 236 may be composed of a lower insulating layer 225, an intermediate insulating layer 230, and an upper insulating layer 235 which are sequentially stacked. The lower insulating layer 225 may be formed of an oxide layer by a deposition method. For example, the lower insulating layer 225 may be formed of a silicon oxide layer by a CVD or ALD method. The intermediate insulating layer 230 may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The upper insulating layer 235 may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In this case, a thickness L3 of the stacked insulating layer covering the sidewalls of the protrusion of the trench isolation layer 121 may be the same as or less than a distance L1 between the sidewalls of the protrusion of the trench isolation layer 121 and the semiconductor substrate edge of the active region A. That is, the sidewalls of the protrusion of the trench isolation layer 121 adjacent to the semiconductor substrate of the active region A are formed in the field region F spaced apart from the semiconductor substrate edge of the active region A by the predetermined distance L1, and the sidewalls may be formed in the field region F spaced apart by at least the same distance as the thickness L3 of the stacked insulating layer covering the sidewalls of the protrusion of the trench isolation layer 121.

Subsequently, a first conductive layer 240, which fills a space between the sidewalls of the protrusion of the trench isolation layer 121, is formed on the entire surface of the semiconductor substrate having the stacked insulating layer 236. The first conductive layer 240 may be at least one layer selected from the group consisting of a polysilicon layer, a tantalum nitride (TaN) layer, a titanium nitride (TiN) layer, a tungsten nitride (WN) layer, and a cobalt silicide (CoSi) layer.

Referring to FIG. 12, the first conductive layer (240 of FIG. 10) and the stacked insulating layer (236 of FIG. 10) are planarized until the top surface of the trench isolation layer 121 is exposed, thereby forming a first conductive pattern and a stacked insulating pattern. The planarization process may employ a CMP or etchback process. The stacked insulating pattern may cover the semiconductor substrate of the active region A and the sidewalls of the protrusion of the trench isolation layer 121. The first conductive pattern may be formed between the sidewalls of the protrusion of the trench isolation layer 121. A top surface of the first conductive pattern and the top surface of the trench isolation layer 121 may be disposed substantially on the same line.

Subsequently, a second conductive layer is formed on the entire surface of the semiconductor substrate having the first conductive pattern. The second conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

Subsequently, the second conductive layer, the first conductive pattern, and the stacked insulating pattern are sequentially patterned, so that an upper conductive pattern 245 crossing the active region A and extending upward from the trench isolation layer 121, a lower conductive pattern 240b disposed between the sidewalls of the protrusion of the trench isolation layer 121 and below the upper conductive pattern on the active region A, and a memory storage pattern 236b interposed between the semiconductor substrate of the active region A and the lower conductive pattern 240b and between the sidewalls of the protrusion of the trench isolation layer 121 and the lower conductive pattern 240b are formed. The memory storage pattern 236b may be composed of a tunnel insulating layer 225b, a charge trap layer 230b, and a blocking insulating layer 235b which are sequentially stacked. The lower conductive pattern 240b and the upper conductive pattern 245 may be electrically connected to each other to form a gate electrode 246.

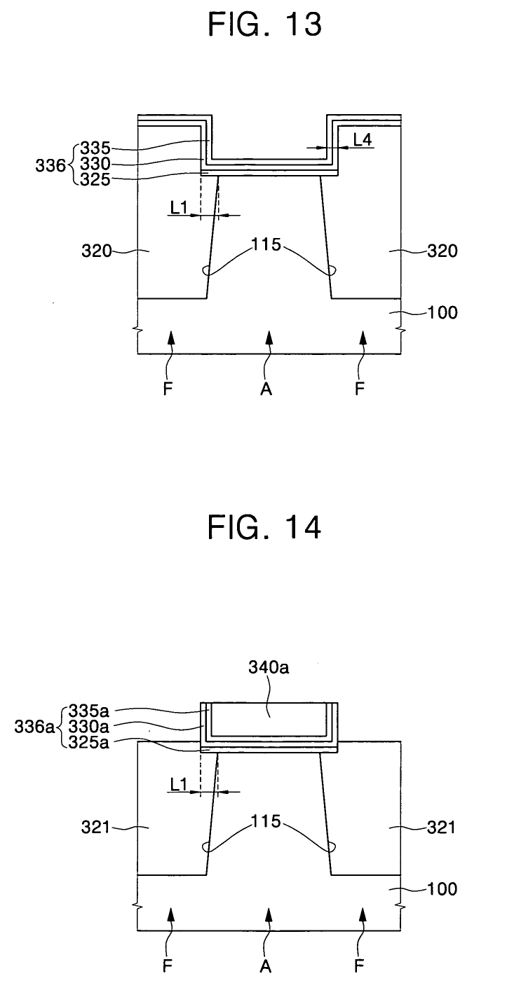

Next, a method of fabricating a non-volatile memory device according to yet other exemplary embodiments of the present invention will be described with reference to FIGS. 13 to 15. Hereinafter, processes up to the formation of the trench 115 are substantially the same as the method described with reference to FIG. 5, and will not be described further with respect to FIGS. 13 to 15.

Referring to FIG. 13, after the mask pattern 111 is formed as described with reference to FIG. 5, the mask pattern 111 is used as an etch mask to form a trench 115. Subsequently, a preliminary trench isolation layer 320 is formed which fills the trench 115 and has a top surface positioned substantially on the same line as a top surface of the mask pattern 111. The preliminary trench isolation layer 320 has a protrusion higher than the surface of the semiconductor substrate of the active region A.

Subsequently, the mask pattern 111 is removed to expose the semiconductor substrate of the active region A. In this case, sidewalls of the protrusion of the preliminary trench isolation layer 320 may be etched by a predetermined amount by the process of removing the mask pattern 111. Accordingly, the sidewalls of the protrusion of the preliminary trench isolation layer 320 may be formed in the field region F spaced apart from the semiconductor substrate edge of the active region by a predetermined distance L1.

Subsequently, a stacked insulating layer 336 is formed on the entire surface of the exposed semiconductor substrate having the active region A. The stacked insulating layer 336 may be composed of a lower insulating layer 325, an intermediate insulating layer 330, and an upper insulating layer 335. To detail this, the lower insulating layer 325 is formed on the exposed semiconductor substrate of the active region A. The lower insulating layer 325 may be formed of a thermal oxide layer. The intermediate insulating layer 330 and the upper insulating layer 335 are sequentially stacked on the entire surface of the semiconductor substrate having the lower insulating layer 325. The intermediate insulating layer 330 may be formed of a high-k dielectric layer. The high-k dielectric layer may be at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer. The upper insulating layer 335 may be at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

In the meantime, the lower insulating layer 325 may be formed of an oxide layer by a deposition method. For example, the lower insulating layer 325 may be formed of a silicon oxide layer by a CVD or ALD method. Accordingly, the lower insulating layer 325 may be conformally formed on the protrusion of the preliminary trench isolation layer 320 and the semiconductor substrate of the active region A.

The sidewalls of the protrusion of the preliminary trench isolation layer 320 are formed in the field region F spaced apart from the semiconductor substrate edge of the active region A adjacent to the field region F by a predetermined distance L1, and the sidewalls may be formed in the field region F spaced apart by at least the same distance as a thickness L4 of the stacked insulating layer covering the sidewalls of the protrusion of the trench isolation layer 320.

Referring to FIG. 14, a first conductive layer is formed on the entire surface of the semiconductor substrate having the stacked insulating layer (336 of FIG. 13). The first conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer. Subsequently, the first conductive layer and the stacked insulating layer (336 of FIG. 13) are planarized until a top surface of the preliminary trench isolation layer (320 of FIG. 13) is exposed, thereby forming a first conductive pattern 340a and a stacked insulating pattern 336a. The planarization process may employ a CMP process or an etchback process. The stacked insulating pattern 336a may cover the semiconductor substrate of the active region A and extend to the sidewalls of the protrusion of the preliminary trench isolation layer (320 of FIG. 12). The stacked insulating pattern 336a may be composed of a lower insulating pattern 325a, an intermediate insulating pattern 330a, and an upper insulating pattern 335a which are sequentially stacked. The first conductive pattern 340a may be formed between the sidewalls of the protrusion of the preliminary trench isolation layer (320 of FIG. 13). Atop surface of the first conductive pattern 340a and a top surface of the preliminary trench isolation layer (320 of FIG. 12) may be disposed substantially on the same line.

Subsequently, the preliminary trench isolation layer (320 of FIG. 12) is selectively and partially etched to form a trench isolation layer 321 which fills the trench 115 and has a top surface higher than the surface of the semiconductor substrate of the active region A and lower than the top surface of the first conductive pattern 340a. In this case, the trench isolation layer 321 preferably has a top surface on or lower than an extended line of an intermediate region of the first conductive pattern 340a. The trench isolation layer 321 may electrically isolate the active region A from its adjacent active regions.

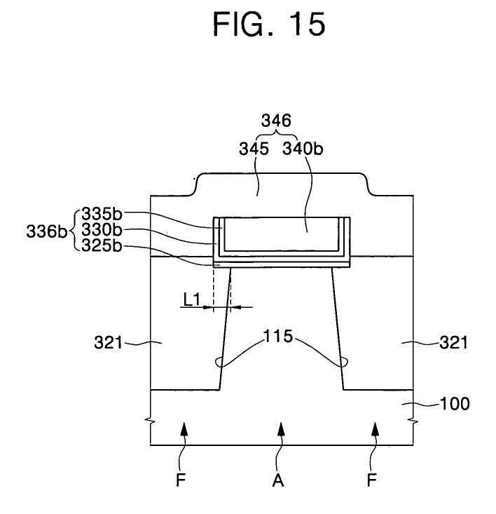

Referring to FIG. 15, a second conductive layer is formed on the entire surface of the semiconductor substrate having the trench isolation layer 321. The second conductive layer may be formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

Subsequently, the second conductive layer, the first conductive pattern (340a of FIG. 14), and the stacked insulating pattern (336a of FIG. 14) are sequentially patterned, so that an upper conductive pattern 345 crossing the active region A and extending upward from the trench isolation layer 321, a lower conductive pattern 340b disposed below the upper conductive pattern on the active region A, and a memory storage pattern 336b disposed below the lower conductive pattern 340b and covering the sidewalls of the lower conductive pattern 340b adjacent to the field region F are sequentially formed. The memory storage pattern 336b may be composed of a tunnel insulating layer 335b formed at least on the semiconductor substrate of the active region A, and a charge trap layer 330b and a blocking insulating layer 325b sequentially stacked on the tunnel insulating layer 335b and extending from the tunnel insulating layer 335b to cover the sidewalls of the lower conductive pattern 340b. The lower conductive pattern 340b and the upper conductive pattern 345 may be electrically connected to each other to form a gate electrode 346.

In this case, a bottom surface of the upper conductive pattern on the field region F may be lower than a top surface of the lower conductive pattern 340b. To detail this, the bottom surface of the upper conductive pattern on the field region F may be higher than the top surface of the trench isolation layer 321 and lower than an intermediate region of the lower conductive pattern 340b. As a result, a predetermined portion of the upper conductive pattern is disposed between the lower conductive pattern 340b and another lower conductive pattern adjacent to the lower conductive pattern, although not shown in FIG. 15. Accordingly, coupling capacitance which might occur between the lower conductive pattern 340b and the other lower conductive pattern adjacent to the lower conductive pattern 340b may be minimized.

In addition, the top surface of the trench isolation layer 321 is in direct contact with the gate electrode 346. As a result, the memory storage pattern 336b is not formed on the trench isolation layer 321 which electrically isolates the active region A from its adjacent active regions, so that disturbance which can occur at the time of operating the non-volatile memory device due to the adjacent cell may be minimized even when the pitches of the active and field regions are reduced due to high integration of the non-volatile memory device. That is, the memory storage pattern 336b is isolated by the trench isolation layer 321, so that charges trapped in the memory storage pattern 336b, in particular, the charge trap layer 330b, may be suppressed from moving between cells. Accordingly, the characteristic of the non-volatile memory device, e.g. data retention capability may be enhanced.

In addition, the memory storage pattern may extend to the field region F from the active region A. Accordingly, the memory storage pattern may be formed without any damage on the active region A where program and erase operations of the non-volatile memory device are substantially executed.

Consequently, characteristic degradation and reliability of the memory storage pattern may be improved. Accordingly, characteristics of the non-volatile memory device, e.g. program and erase operations, and endurance may be enhanced.

According to the present invention as mentioned above, the memory storage pattern on the active region may be formed without any damage resulting from a process of forming the trench isolation layer. As a result, characteristic degradation and reliability of the memory storage pattern may be improved. Accordingly, characteristics of the non-volatile memory device, e.g. program and erase operations, and endurance may be enhanced. In addition, the memory storage pattern is isolated from its adjacent memory storage patterns, so that charges trapped in the memory storage pattern, in particular, the charge trap layer, may be suppressed from moving between cells. Accordingly, data retention capability of the non-volatile memory device may be enhanced.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A non-volatile memory device, comprising:
a semiconductor substrate having an active region and a field region;
a trench isolation layer disposed in the semiconductor substrate field region to define the active region, and having a protrusion higher than a top surface of the semiconductor substrate active region;
a memory storage pattern crossing the semiconductor substrate active region, extending from the semiconductor substrate active region, and covering sidewalls of the protrusion of the trench isolation layer; and
a gate electrode disposed on the memory storage pattern and extending upward from the trench isolation layer.

2. The non-volatile memory device according to claim 1, wherein the trench isolation layer has a top surface higher than a top surface of the memory storage pattern on the active region.

3. The non-volatile memory device according to claim 1, wherein the sidewalls of the protrusion of the trench isolation layer are disposed in the field region spaced apart from an edge of the semiconductor substrate active region by a predetermined distance, and spaced apart by at least the same distance as a thickness of the memory storage pattern covering the sidewalls of the protrusion of the trench isolation layer.

4. The non-volatile memory device according to claim 1, wherein the memory storage pattern is composed of a tunnel insulating layer formed at least on the semiconductor substrate active region, and a charge trap layer and a blocking insulating layer sequentially stacked on the tunnel insulating layer and extending to the sidewalls of the protrusion of the trench isolation layer.

5. The non-volatile memory device according to claim 4, wherein the tunnel insulating layer is formed of one selected from the group consisting of a thermal oxide layer, a chemical vapor deposition (CVD) oxide layer, and an atomic layer deposition (ALD) oxide layer.

6. The non-volatile memory device according to claim 4, wherein the charge trap layer is a high-k dielectric layer.

7. The non-volatile memory device according to claim 6, wherein the high-k dielectric layer is at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

8. The non-volatile memory device according to claim 4, wherein the blocking insulating layer is at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

9. The non-volatile memory device according to claim 1, wherein the gate electrode is composed of a lower conductive pattern which is formed between the sidewalls of the protrusion of the trench isolation layer and has a top surface disposed substantially on the same line as a top surface of the trench isolation layer, and an upper conductive pattern which covers the lower conductive pattern and has a flat top surface extending upward from the trench isolation layer.

10. The non-volatile memory device according to claim 9, wherein the lower conductive pattern is at least one layer selected from the group consisting of a polysilicon layer, a tantalum nitride (TaN) layer, a titanium nitride (TiN) layer, a tungsten nitride (WN) layer, and a cobalt silicide (CoSi) layer.

11. The non-volatile memory device according to claim 9, wherein the upper conductive pattern is at least one layer selected from the group consisting of a polysilicon layer, a tantalum nitride (TaN) layer, a titanium nitride (TiN) layer, a tungsten nitride (WN) layer, and a cobalt silicide (CoSi) layer.

12. A non-volatile memory device, comprising:
a semiconductor substrate having an active region and a field region;
a trench isolation layer disposed in the semiconductor substrate field region to define the active region, and having a protrusion higher than a top surface of the semiconductor substrate active region;
a lower conductive pattern disposed on the semiconductor substrate active region and having a top surface higher than a top surface of the trench isolation layer;
a memory storage pattern surrounding sidewalls and a bottom surface of the lower conductive pattern, being self-aligned with the bottom surface of the lower conductive pattern, and covering sidewalls of the lower conductive pattern adjacent to the field region; and
an upper conductive pattern covering the lower conductive pattern and extending upward from the trench isolation layer.

13. The non-volatile memory device according to claim 12, wherein the top surface of the protrusion of the trench isolation layer is lower than or disposed on an extended line of an intermediate region of the lower conductive pattern.

14. The non-volatile memory device according to claim 12, wherein the sidewalls of the protrusion of the trench isolation layer are disposed in the field region spaced apart from an edge of the semiconductor substrate active region by a predetermined distance, and spaced by at least the same distance as a thickness of the memory storage pattern covering the sidewalls of the lower conductive pattern.

15. The non-volatile memory device according to claim 12, wherein the memory storage pattern is composed of a tunnel insulating layer formed at least on the semiconductor substrate active region, and a charge trap layer and a blocking insulating layer sequentially stacked on the tunnel insulating layer and extending from the tunnel insulating layer to cover the sidewalls of the lower conductive pattern.

16. The non-volatile memory device according to claim 15, wherein the tunnel insulating layer is one selected from the group consisting of a thermal oxide layer, a chemical vapor deposition (CVD) oxide layer, and an atomic layer deposition (ALD) oxide layer.

17. The non-volatile memory device according to claim 15, wherein the charge trap layer is a high-k dielectric layer.

18. The non-volatile memory device according to claim 17, wherein the high-k dielectric layer is at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

19. The non-volatile memory device according to claim 15, wherein the blocking insulating layer is at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

20. The non-volatile memory device according to claim 12, wherein the lower conductive pattern is at least one layer selected from the group consisting of a polysilicon layer, a tantalum nitride (TaN) layer, a titanium nitride (TiN) layer, a tungsten nitride (WN) layer, and a cobalt silicide (CoSi) layer.

21. The non-volatile memory device according to claim 12, wherein the upper conductive pattern is at least one layer selected from the group consisting of a polysilicon layer, a tantalum nitride (TaN) layer, a titanium nitride (TiN) layer, a tungsten nitride (WN) layer, and a cobalt silicide (CoSi) layer.

22. A method of fabricating a non-volatile memory device, comprising:
preparing a semiconductor substrate having an active region and a field region;
forming a trench isolation layer having a protrusion higher than a surface of the semiconductor substrate active region in the semiconductor substrate field region;
forming a stacked insulating layer covering the semiconductor substrate active region and the protrusion of the trench isolation layer;
forming a first conductive layer on the semiconductor substrate having the stacked insulating layer;
planarizing the first conductive layer and the stacked insulating layer until the top surface of the trench isolation layer is exposed, and forming a first conductive pattern remaining on the active region while forming a stacked insulating pattern covering the semiconductor substrate active region and sidewalls of the protrusion of the trench isolation layer;
forming a second conductive layer on the entire surface of the semiconductor substrate having the stacked insulating pattern and the first conductive pattern; and
sequentially patterning the second conductive layer, the first conductive pattern, and the stacked insulating pattern, and sequentially forming an upper conductive pattern crossing the active region and extending upward from the trench isolation layer, a lower conductive pattern disposed between the sidewalls of the protrusion of the trench isolation layer and below the upper conductive pattern on the active region, and a memory storage pattern covering the semiconductor substrate active region and the sidewalls of the protrusion of the trench isolation layer.

23. The method according to claim 22, wherein the sidewalls of the protrusion of the trench isolation layer are formed in the field region spaced apart from an edge of the semiconductor substrate active region by a predetermined distance, the sidewalls of the protrusion of the trench isolation layer being formed in the field region spaced by at least the same distance as a thickness of the stacked insulating layer covering the sidewalls of the protrusion of the trench isolation layer.

24. The method according to claim 22, wherein the stacked insulating layer is composed of a lower insulating layer formed at least on the semiconductor substrate active region, and an intermediate insulating layer and an upper insulating layer conformally and sequentially formed on the entire surface of the semiconductor substrate having the active region.

25. The method according to claim 24, wherein the lower insulating layer is formed of one selected from the group consisting of a thermal oxide layer, a chemical vapor deposition (CVD) oxide layer, and an atomic layer deposition (ALD) oxide layer.

26. The method according to claim 24, wherein the intermediate insulating layer is formed of a high-k dielectric layer.

27. The method according to claim 26, wherein the high-k dielectric layer is formed of at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

28. The method according to claim 24, wherein the upper insulating layer is formed of at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

29. The method according to claim 22, wherein the first conductive layer is formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

30. The method according to claim 22, wherein the second conductive layer is formed of one selected from the group consisting of a polysilicon layer, a tantalum nitride (TaN) layer, a titanium nitride (TiN) layer, a tungsten nitride (WN) layer, and a cobalt silicide (CoSi) layer.

31. A method of fabricating a non-volatile memory device, comprising:
preparing a semiconductor substrate having an active region and a field region;
forming a preliminary trench isolation layer having a protrusion higher than a surface of the semiconductor substrate active region in the semiconductor substrate field region;
forming a stacked insulating layer covering the semiconductor substrate active region and the protrusion of the preliminary trench isolation layer;
forming a first conductive layer on the semiconductor substrate having the stacked insulating layer;
planarizing the first conductive layer and the stacked insulating layer until the top surface of the preliminary trench isolation layer is exposed, and forming a first conductive pattern remaining on the active region while forming a stacked insulating pattern covering the semiconductor substrate active region and sidewalls of the protrusion of the preliminary trench isolation layer;
selectively and partially etching the preliminary trench isolation layer, and forming a trench isolation layer having a top surface higher than a surface of the semiconductor substrate active region and lower than an intermediate region of the first conductive pattern;
forming a second conductive layer on the entire surface of the semiconductor substrate having the trench isolation layer; and
sequentially patterning the second conductive layer, the first conductive pattern, and the stacked insulating pattern, and sequentially forming an upper conductive pattern crossing the active region and extending upward from the trench isolation layer, a lower conductive pattern disposed below the upper conductive pattern on the active region, and a memory storage pattern disposed below the lower conductive pattern and covering sidewalls of the lower conductive pattern adjacent to the field region.

32. The method according to claim 31, wherein the sidewalls of the protrusion of the preliminary trench isolation layer are formed in the field region spaced apart from an edge of the semiconductor substrate active region by a predetermined distance, the sidewalls of the protrusion of the preliminary trench isolation layer being formed in the field region spaced apart by at least the same distance as a thickness of the stacked insulating layer covering the sidewalls of the protrusion of the preliminary trench isolation layer.

33. The method according to claim 31, wherein the stacked insulating layer is composed of a lower insulating layer formed at least on the semiconductor substrate active region, and an intermediate insulating layer and an upper insulating layer conformally and sequentially formed on the entire surface of the semiconductor substrate having the active region.

34. The method according to claim 33, wherein the lower insulating layer is formed of one selected from the group consisting of a thermal oxide layer, a chemical vapor deposition (CVD) oxide layer, and an atomic layer deposition (ALD) oxide layer.

35. The method according to claim 33, wherein the intermediate insulating layer is formed of a high-k dielectric layer.

36. The method according to claim 35, wherein the high-k dielectric layer is formed of at least one layer selected from the group consisting of a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

37. The method according to claim 33, wherein the upper insulating layer is formed of at least one layer selected from the group consisting of a silicon oxide layer, a silicon nitride (SiN) layer, an aluminum oxide (AlO) layer, a hafnium oxide (HfO) layer, a hafnium-aluminum oxide (HfAlO) layer, and a hafnium-silicon oxide (HfSiO) layer.

38. The method according to claim 31, wherein the first conductive layer is formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.

39. The method according to claim 31, wherein the second conductive layer is formed of at least one layer selected from the group consisting of a polysilicon layer, a tantalum nitride (TaN) layer, a titanium nitride (TiN) layer, a tungsten nitride (WN) layer, and a cobalt silicide (CoSi) layer.
